(19) United States
(12) Patent Application Publication
(10) Pub. No.: US 2005/0158972 A1
(43) Pub. Date: Jul. 21, 2005

(54) Method for manufacturing bit line contact structure of semiconductor memory

(75) Inventors: Feng-Chuan Lin, Taipei (TW); Yi-Nan Chen, Taipei (TW); Ping Hsu, Taipei (TW)

Correspondence Address: BACON & THOMAS, PLLC, 625 SLATERS LANE, FOURTH FLOOR, ALEXANDRIA, VA, 22314, US

(73) Assignee: Nanya Technology Corporation, Taoyuan (TW)

(21) Appl. No.: 10/759,058

(22) Filed: Jan. 20, 2004

(51) Int. Cl. H01L 21/3205

(52) U.S. Cl. 438/586

(57) ABSTRACT

A method is disclosed for manufacturing bit line contact structures of semiconductor memories. The manufacturing method comprises the steps of providing a semiconductor substrate, forming a plurality of gates on the surface of the substrate, applying a first insulating layer to cover the surface of the substrate and the gates, selectively forming a plurality of gate contact windows at the locations of the gates, selectively forming bit line contact windows in the first insulating layer, the bit line contact windows contacting the substrate, and filling the gate contact windows and the bit line contact windows with a conductive layer.

### BACKGROUND OF THE INVENTION

1. Field of the Invention

The present invention relates to a method for manufacturing a semiconductor memory, more specifically, to a method for manufacturing a bit line contact structure of a semiconductor memory.

2. Description of the Prior Art

Generally, a semiconductor memory manufacturing method uses a contact window to form a contact structure, so as to connect inner parts with external circuits. Take semiconductor memory DRAM process as an example, steps for forming a bit line contact structure are shown in FIGS. 1a to 1d. In FIG. 1a, a plurality of gates 12 are formed on a semiconductor substrate 11. Usually, the semiconductor substrate 11 is a silicon substrate. Each of the gates 12 comprises poly-silicon, WSi and nitride and has spacer 13 on the sidewall thereof. Then, as shown in FIG. 1b, a SiN layer 14 and a BPSG layer 15 are applied to cover the surface of the semiconductor substrate 11 and the gates 12. The silicon nitride layer 14 acts as a barrier layer to prevent the components such as boron and phosphorus of the BPSG layer, which is used as an insulating layer, from diffusing outward. Planarization such as CMP (chemical mechanical polishing) can be performed to expose the upper surfaces of the gates 12. Subsequently, in FIG. 1c, a TEOS (tetraethyl orthsilicate) layer 16 is formed on the upper surface of the entire structure as an insulating layer. On the TEOS layer 16, a photoresist layer 17 with a predetermined pattern is formed. The photoresist layer 17 has an opening 171. At the position defined by the opening 171, the portions of the layers 15 and 16 are removed by etching to form a bit line contact window 18. Then the photoresist layer 17 is removed. The bit line contact window 18 is filled with conductive material to form a bit line contact structure. However, since it takes a long time to remove the layers 15, 16 and 17, the shoulder portions of the gates 15 and the spacers 13 are often damaged so that the inner WSi conductive layer of the gate 15 is exposed, as shown in FIG. 1 d. Accordingly, the conductive material filling the bit line contact window 18 will contact the inner WSi conducting layer of the gate 12 to cause a short circuit.

Therefore, there is a need for a solution to overcome the problems stated above. The present invention satisfies such a need.

### SUMMARY OF THE INVENTION

An objective of the present invention is to provide a method for manufacturing a bit line contact structure of a semiconductor memory, which can maintain the completeness of a gate structure to avoid improper shirt circuit between the bit line and the gate.

In accordance with an embodiment of the present invention, the method for manufacturing a bit line contact structure of a semiconductor memory comprises steps of providing a semiconductor substrate; forming a plurality of gates on the surface of the semiconductor substrate; applying a first insulating layer to cover the substrate surface and the gates; selectively forming a plurality of gate contact windows at the positions of the gates; selectively forming a bit line contact window in the first insulating layer to communicate with the semiconductor substrate; and filling the gate contact windows and the bit line contact window with conductive material.

In accordance with another embodiment of the present invention, the method for manufacturing a bit line contact structure of a semiconductor memory comprises steps of providing a semiconductor substrate; forming a plurality of gates on the surface of the semiconductor structure; applying a first insulating layer to cover the semiconductor surface and the gates; performing planarization to expose the upper surfaces of the gates; selectively forming a plurality of gate contact windows at the upper surfaces of the gates; selectively forming a bit line contact window in the first insulating layer to communicate with the semiconductor substrate; filling the gate contact windows and the bit line contact window with a conductive layer; forming a second insulating layer with a predetermined pattern on the upper surface of the entire structure such that the conductive layer is exposed; and forming a metal layer on the exposed conductive layer.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIGS. 1a to 1d are schematic sectional diagrams illustrating respective steps of a conventional DRAM semiconductor memory process for forming a bit line contact structure; and

FIGS. 2a to 2e are schematic sectional diagrams illustrating the respective steps of the method in accordance with the present invention.

### DETAILED DESCRIPTION OF THE PREFERRED EMBODIMENT

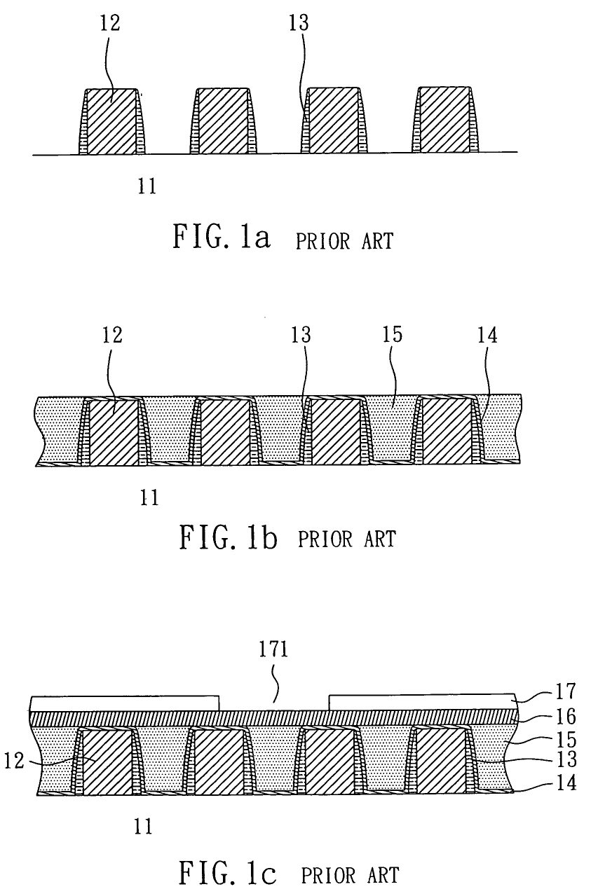

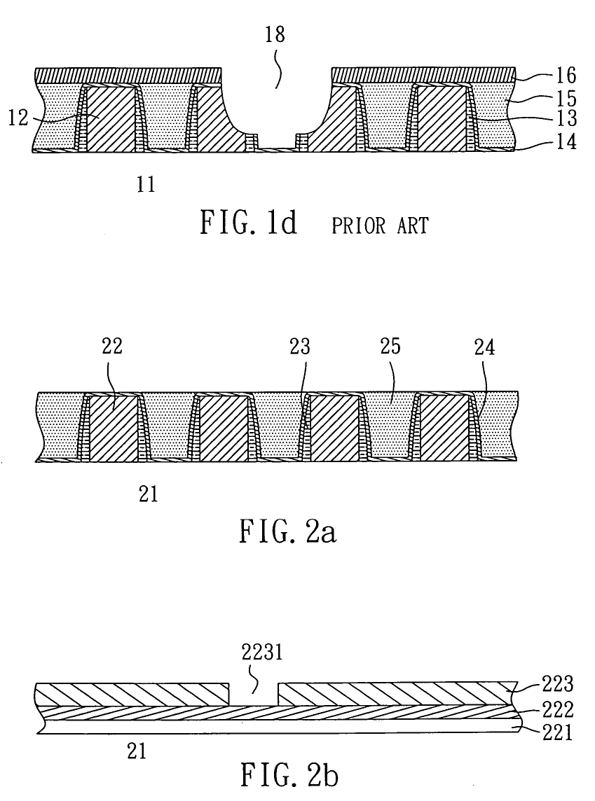

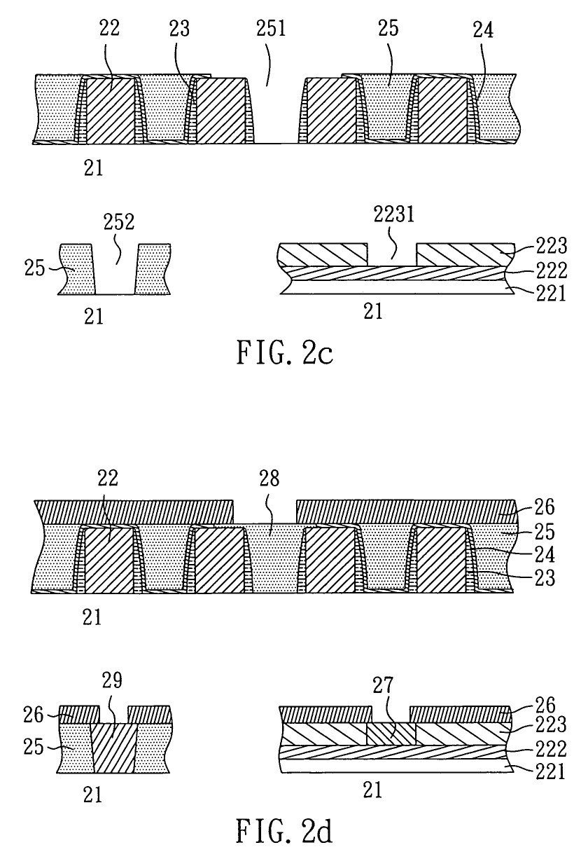

An embodiment of the present invention will be described in detail with reference to the accompanying drawings. FIGS. 2a to 2e are schematic sectional diagrams illustrating the respective steps of the method in accordance with the present invention. The structure shown in FIG. 2a is substantially the same as that shown in FIGS. 1a and 1b. The structure has a substrate 21, gates 22, spacer 23, a SiN layer 24 as a barrier, and a BPSG layer 25 as an insulating layer. The layer 25 can be planarized by CMP, for instance, to expose the upper surfaces of the gates 22. As shown in FIG. 2b, each gate 22 generally comprises a poly-silicon layer 221, a WSi layer 222 and a nitride layer 223.

Then, in FIG. 2b, an opening 2231 of a predetermined pattern is formed in the nitride layer 223 of the gate 22 by etching, for instance, as a gate contact window.

Next, as shown in FIG. 2c, an opening 251 communicating with the substrate 21 is formed by etching, for instance, in the layer 25 as a bit line contact window. At the same time, an opening 252 communicating with the substrate 21 is formed in the layer 25 by etching, for instance, as a substrate contact window.

FIG. 2d illustrates that the gate contact window, bit line contact window and substrate contact window are filled with conductive layers 27, 28, 29, respectively. The conductive layers preferably comprise W and TiN/Ti, wherein TiN/Ti lies below W. The entire structure is preferably planarized by CMP. Then, a TEOS (tetraethyl orthsilicate) layer 26 of a predetermined pattern is formed on the entire structure as an insulating layer, wherein the conductive layers 27, 28, 29 are exposed.

Subsequently, metal layers 27′, 28′, 29′, generally referred to MO metal layers, are formed on the exposed conductive layers 27, 28, 29, respectively. The metal layer 28′ is used as a bit line. The metal layers comprise W and TiN/Ti, in which TiN/Ti lies beneath W. The resultant structure is preferably planarized by CMP.

As shown in FIG. 2c, when forming the bit line contact window in accordance with the present invention, it is necessary to remove the layer 25 only. Accordingly, the required time is short, the shoulder portions of the gate 22 and the spacer 23 will not be damaged and the completeness therefore can be maintained. Therefore, when the bit line contact window 251 is filled with the conducting layer 28, the conducting layer 28 will not contact the WSi conducting layer 222 inside the gate 12. The short circuit between the bit line 28′ and the gate 12 can be accordingly avoided.

In addition, as compared to FIG. 1c, in which the photoresist layer 17 with the predetermined pattern is formed on the insulating layer 16, the method of the present invention as shown in FIG. 2c, when forming the bit line contact window 251, can form the mask on the thinner layer. Therefore, the variance of the critical dimension is less than the prior art. Furthermore, by the method in accordance with the present invention, it is easy to implement self-aligned contact etching. In the method of the present invention, the conducting layers and the metal layers are formed separately, the occurrence of voids can be prevented.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A method for manufacturing a bit line contact structure of a semiconductor memory, said method comprising steps of:
providing a semiconductor substrate;
forming a plurality of gates on the surface of said substrate;
applying a first insulating layer to cover said surface of said substrate and said gates;
selectively forming a plurality of gate contact windows at the locations of said gates;
selectively forming bit line contact windows in said first insulating layer, said bit line contact windows contacting said substrate; and
filling said gate contact windows and said bit line contact windows with a conductive layer.

2. The method as claimed in claim 1, wherein said semiconductor substrate comprises silicon.

3. The method as claimed in claim 1, wherein said first insulating layer comprises BPSG, and said method further comprising a step of forming a silicon nitride layer to cover said surface of said substrate and said gates before applying the first insulating layer.

4. The method as claimed in claim 1, further comprising a step of performing planarization to expose the upper surfaces of the gates after applying the first insulating layer.

5. The method as claimed in claim 1, wherein the formation of the gate contact windows and the bit line contact windows mainly uses etching.

6. The method as claimed in claim 1, wherein the conductive layer comprises W.

7. The method as claimed in claim 1, wherein the conductive layer further comprises TiN/Ti lying under the W.

8. The method as claimed in claim 1, further comprising steps of:
forming a second insulating layer of a predetermined pattern on the resultant structure after the filling step, wherein the conductive layer is exposed; and
forming a metal layer on the exposed conductive layer.

9. The method as claimed in claim 8, wherein the second insulating layer comprises TEOS.

10. The method as claimed in claim 8, wherein the metal layer comprises W.

11. The method as claimed in claim 10, wherein the metal layer further comprises a TiN/Ti layer lying under the W.

12. A method for manufacturing a bit line contact structure of a semiconductor memory, said method comprising steps of:
providing a semiconductor substrate;
forming a plurality of gates on the surface of said substrate;
applying a first insulating layer to cover said surface of said substrate and said gates;
performing planarization to expose the upper surfaces of the gates;
selectively forming a plurality of gate contact windows at the locations of the upper surfaces of said gates;
selectively forming bit line contact windows in said first insulating layer, said bit line contact windows contacting said substrate;
filling said gate contact windows and said bit line contact windows with a conductive layer;
forming a second insulating layer of a predetermined pattern on the resultant structure, wherein the conductive layer is exposed; and
forming a metal layer on the exposed conductive layer.

13. The method as claimed in claim 12, wherein said semiconductor substrate comprises silicon.

14. The method as claimed in claim 12, wherein said first insulating layer comprises BPSG, and said method further comprising a step of forming a silicon nitride layer to cover said surface of said substrate and said gates before applying the first insulating layer.

15. The method as claimed in claim 12, wherein the formation of the gate contact windows and the bit line contact windows mainly uses etching.

16. The method as claimed in claim 12, wherein the conductive layer comprises W.

17. The method as claimed in claim 16, wherein the conductive layer further comprises a TiN/Ti layer lying under the W.

18. The method as claimed in claim 12, wherein the second insulating layer comprises TEOS.

19. The method as claimed in claim 12, wherein the metal layer comprises W.

20. The method as claimed in claim 19, wherein the metal layer further comprises a TiN/Ti layer lying under the W.
